(19) United States
(12) Patent Application Publication
(10) Pub. No.: US 2026/0072358 A1
(43) Pub. Date: Mar. 12, 2026

(54) MASK PATTERN DETERMINATION METHOD, APPARATUS, MEDIUM, AND PROGRAM PRODUCT

(71) Applicant: DONGFANG JINGYUAN ELECTRON CO., LTD., Beijing (CN)

(72) Inventors: Shengrui Zhang, Beijing (CN); Zongqiang Yu, Beijing (CN); Weijie Shi, Beijing (CN); Hangyu Wang, Beijing (CN); Chengjin Wang, Beijing (CN); Fengsheng Zhao, Beijing (CN); Yanbin Gong, Beijing (CN)

(21) Appl. No.: 19/388,320

(22) Filed: Nov. 13, 2025

(30) Foreign Application Priority Data
Mar. 11, 2025 (CN) 202510287654.5

(51) Int. Cl. G03F 7/00; G03F 1/36

(52) U.S. Cl. CPC G03F 7/70441; G03F 1/36

(57) ABSTRACT

The present application discloses a mask pattern determination method, apparatus, medium, and program product, which are applied to the technical field of semiconductor. In the mask pattern determination method provided in the present application, a target mask pattern is determined based on a plurality of second sampling points, and the second sampling points are obtained by performing etching bias correction on a first sampling point based on a first etching deviating data between a position corresponding to a first sampling point on the first photolithography pattern and a position corresponding to the first sampling point on the first etch pattern. The first sampling point may represent a pattern contour of the first target etch pattern. Therefore, in the present application, an etching bias of a curved contour may be corrected relatively accurately by correcting the plurality of sampling points individually.

### CROSS-REFERENCE TO RELATED APPLICATIONS

This application claims priority to Chinese Patent Application No. 202510287654.5, filed on Mar. 11, 2025, which is hereby incorporated by reference in its entirety.

### TECHNICAL FIELD

The present application relates to the technical field of semiconductors, and in particular to a mask pattern determination method, apparatus, medium, and program product.

### BACKGROUND

The core step of semiconductor chip manufacturing is to transfer the designed pattern of a chip to a wafer. Among the multiple process steps of chip manufacturing, the processes directly related to the pattern transfer are mainly photolithography and etching. Both the photolithography process and the etching process will produce bias, which will bring about difference among the mask pattern, the photoresist pattern and the etch pattern. Therefore, when designing the mask pattern, it is necessary to correct the photolithography and etching biases. In a case that a device pattern in a layout is rectangular, when performing etching bias correction, since the device pattern is composed of straight lines, at present, the corresponding etching bias is determined according to the line width and space of the edges of a current polygon, and then etching bias correction is performed on the corresponding edges.

### SUMMARY

In one aspect, the embodiments of the present application provide a mask pattern determination method, which comprises acquiring a first target etch pattern and a plurality of first sampling points for characterizing a pattern contour of the first target etch pattern, the pattern contour comprising a curved contour; performing optical proximity effect correction on the first target etch pattern to obtain a first mask pattern; performing photolithography simulation on the first mask pattern to obtain a first photolithography pattern, and performing photolithography etching simulation on the first mask pattern to obtain a first etch pattern; determining, for each of the first sampling points, a first etching bias data between a position corresponding to a first sampling point on the first photolithography pattern and a position corresponding to the first sampling point on the first etch pattern individually; performing, on each of the first sampling points, etching bias correction based on the first etching deviating data to obtain a plurality of second sampling points; and determining a target mask pattern based on the plurality of second sampling points.

Specifically, a step of determining a target mask pattern based on the plurality of second sampling points comprises generating a target photolithography pattern based on the plurality of second sampling points; performing optical proximity effect correction on the target photolithography pattern to obtain a second mask pattern; performing photolithography simulation on the second mask pattern to obtain a second photolithography pattern, and performing photolithography etching simulation on the second mask pattern to obtain a second etch pattern; determining, for each of the second sampling points, a second etching deviating data between a position corresponding to a second sampling point on the second photolithography pattern and a position corresponding to the second sampling point on the second etch pattern individually; performing, in a case that the second etching deviating data does not satisfy a preset condition, etching bias correction on the second sampling point based on the second etching deviating data to obtain a third sampling point; replacing each of the plurality of second sampling points with the corresponding third sampling point, and returning to a step of generating a target photolithography pattern based on the plurality of second sampling points until the second etching deviating data satisfies the preset condition; and determining a current second mask pattern as the target mask pattern in a case that the second etching deviating data satisfies the preset condition.

Specifically, a step of determining a target mask pattern based on the plurality of second sampling points comprises generating a target photolithography pattern based on the plurality of second sampling points; and performing optical proximity effect correction on the target photolithography pattern to obtain the target mask pattern.

Specifically, a step of performing optical proximity effect correction on the first target etch pattern to obtain a first mask pattern comprises performing Manhattanization on the first target etch pattern to obtain a corresponding Manhattan pattern; and performing optical proximity effect correction on the Manhattan pattern to obtain the first mask pattern.

Specifically, the pattern contour further comprises a straight-line contour; and acquiring a plurality of first sampling points for characterizing a pattern contour of the first target etch pattern comprises acquiring, for a straight-line contour in the first target etch pattern, at least one point on a straight line as a feature point; acquiring, for a curved contour in the first target etch pattern, curved contour points at preset intervals; and determining the feature point and the curved contour points as the first sampling points.

Specifically, a step of determining, for each of the first sampling points, a first etching deviating data between a position corresponding to a first sampling point on the first photolithography pattern and a position corresponding to the first sampling point on the first etch pattern individually comprises determining, for each of the first sampling points, a deviating distance and a deviating direction between a position corresponding to a first sampling point on the first photolithography pattern and a position corresponding to the first sampling point on the first etch pattern individually. Correspondingly, a step of performing, for each of the first sampling points, etching bias correction on the first sampling point based on the first etching deviating data to obtain a plurality of second sampling points comprises moving each of the first sampling points by the corresponding deviating distance in an opposite direction to the deviating direction to obtain the plurality of second sampling points.

Specifically, the performing photolithography simulation on the first mask pattern to obtain a first photolithography pattern comprises inputting the first mask pattern to a photolithography simulation model to obtain the first photolithography pattern; and the performing photolithography etching simulation on the first mask pattern to obtain a first etch pattern comprises inputting the first photolithography pattern to an etching simulation model to obtain the first etch pattern.

Specifically, the etching simulation model comprises a merging unit, a neural network unit, and at least one physical effect simulation unit. A step of inputting the first photolithography pattern to an etching simulation model to obtain the first etch pattern comprises inputting the first photolithography pattern to the at least one physical effect simulation unit to obtain at least one first sub-image correspondingly, and inputting the first photolithography pattern to the neural network unit to obtain a second sub-image, the neural network unit being trained based on a photolithography pattern sample and a corresponding etch image label; and merging the at least one first sub-image and the second sub-image by the merging unit to obtain the first etch pattern.

In another aspect, the embodiments of the present application provide a mask pattern determination apparatus, which comprises a processor and a memory storing computer program instructions, wherein the processor, when executes the computer program instructions, carries out the aforesaid mask pattern determination method.

In still another aspect, the embodiments of the present application provide a computer-readable storage medium, wherein the computer-readable storage medium stores computer program instructions which, when being executed by a processor, carry out the aforesaid mask pattern determination method.

In yet another aspect, the embodiments of the present application provide a computer program product, wherein when instructions in the computer program product are executed by a processor of an electronic device, the electronic device is caused to carry out the aforesaid mask pattern determination method.

### BRIEF DESCRIPTION OF THE DRAWINGS

In order to explain the technical solutions of the embodiments of the present application more clearly, a brief introduction to the drawings for the embodiments of the present application will be provided below. For a person skilled in the art, additional drawings may be derived from these drawings without inventive efforts.

FIG. 1 shows a flow chart of a first mask pattern determination method according to an embodiment of the present application;

FIG. 2 shows a flow chart of a second mask pattern determination method according to an embodiment of the present application;

FIG. 3 shows a flow chart of determining a target mask pattern by multiple iterations according to an embodiment of the present application;

FIG. 4 shows a schematic view of performing Manhattanization on a first target etch pattern according to an embodiment of the present application;

FIG. 5 shows a flow chart of a third mask pattern determination method according to an embodiment of the present application;

FIG. 6 shows a schematic view of a simulation process of an etching simulation model according to an embodiment of the present application;

FIG. 7 shows a schematic view of etching bias correction according to an embodiment of the present application;

FIG. 8 shows a schematic structural view of a mask pattern determination apparatus according to an embodiment of the present application; and

FIG. 9 shows a schematic structural view of a hardware of a mask pattern determination apparatus according to an embodiment of the present application.

### DETAILED DESCRIPTION

Features and exemplary embodiments of various aspects of the present application will be described in detail below. In order to make the objects, technical solutions and advantages of the present application more clear, the present application will be further described in detail below with reference to the drawings and specific embodiments. It should be understood that, the specific embodiments described herein are only intended to explain the present application, but not to limit the present application. For those of ordinary skilled in the art, the present application may be implemented without some of those specific details. The following description of the embodiments is only for providing a better understanding of the present application by showing examples.

It should be noted that, relational terms such as first, second, and the like are used herein merely for distinguishing one entity or operation from another without necessarily requiring or implying any such actual relationship or order between such entities or operations. Moreover, the terms “include”, “comprise”, or any other variation thereof, are intended to cover a non-exclusive inclusion, such that a(n) process, method, article or device that includes a series of elements not only includes those elements but also includes other elements not explicitly listed or also includes elements inherent to such process, method, article or device. An element preceded by “include . . . ” does not, without more constraints, preclude the existence of additional identical elements in the process, method, article or device that includes the element.

The core step of semiconductor chip manufacturing is to transfer the designed pattern of a chip to a wafer. Among the multiple process steps of chip manufacturing, the processes directly related to the pattern transfer are mainly photolithography and etching. The photolithography technology works by using photoresist that undergoes chemical reactions when exposed to light of special wavelength, and then a pattern designed on a mask is transferred to a photoresist pattern on a silicon wafer through development. Then the etching process selectively removes unwanted materials with the assistance of the photoresist pattern, thereby creating a desired fine pattern on the silicon wafer. The etching process will cause the etching bias, that is, the photoresist line width before the etching process is different from that after the etching process.

Therefore, when designing a mask pattern, the photolithography bias and the etching bias need to be corrected. In a case that a device pattern in a layout is rectangular, when performing etching bias correction, since the device pattern is composed of straight lines, at present, the corresponding etching bias is determined according to the line width and space of the edges of a current polygon, and then the etching bias correction is performed on the corresponding edges.

However, the above method is not applicable to patterns where the device pattern includes a curved contour, such as a pattern of a silicon photonic device. The etching bias correction of a curved pattern cannot be accurately performed by the above solution, resulting in that the design of the mask pattern corresponding to the curved pattern cannot be effectively implemented. When the etching bias correction is performed by a traditional solution, an entire straight-line edge will be directly moved. However, for a curved pattern, different positions on the curve correspond to different etching biases, and thus the etching bias correction of a curved contour cannot be accurately performed by the traditional solution.

In view of the problem in the traditional solution, since different positions on the curved contour correspond to different etching biases, moving the entire curved contour cannot take different positions on the contour into consideration. Under this condition, sampling points at a plurality of different positions on the curved contour may be acquired, and the etching bias corresponding to each individual sampling point is acquired and corrected (compensated). Then, a new pattern is generated based on the corrected sampling points to obtain a corrected curved contour. In this manner, the plurality of positions on the curved contour may be taken into consideration, thereby accurately performing etching bias correction on the entire curved contour.

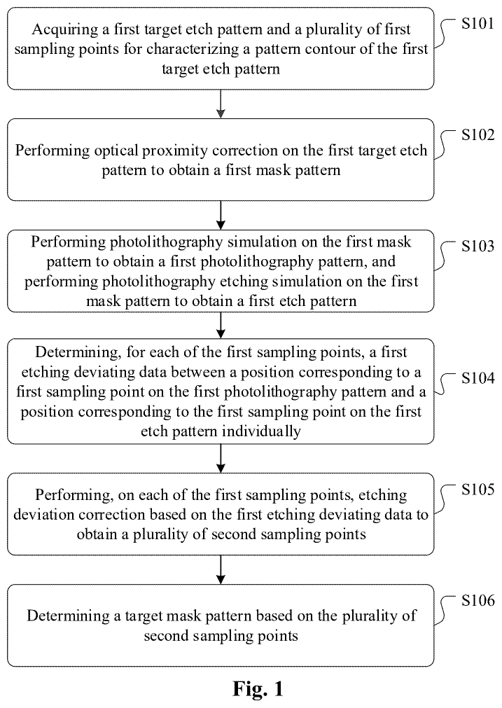

On this basis, the embodiments of the present application provide a mask pattern determination method, apparatus, medium, and program product. The mask pattern determination method provided in the embodiments of the present application will be firstly introduced below. FIG. 1 shows a flow chart of a first mask pattern determination method according to an embodiment of the present application. As shown in FIG. 1, the method includes following steps S101 to S106.

S101: a first target etch pattern and a plurality of first sampling points for representing a pattern contour of the first target etch pattern are acquired.

In the mask pattern design scenario, the first target etch pattern is an actually desired wafer pattern. In order to facilitate the etching bias correction on the first target etch pattern, it is necessary to firstly obtain the plurality of first sampling points that may represent the pattern contour of the first target etch pattern.

The pattern contour of the first target etch pattern mentioned in the present application includes a curved contour. In practical applications, a specific type of the first target etch pattern is not limited. The first target etch pattern may be a pattern consisting of only curved contours, or may be a pattern consisting of both straight-line contours and curved contours.

The method for acquiring the first sampling points is not specifically limited in the embodiments of the present application, and may be determined according to actual conditions. As an optional embodiment, for different types of first target etch patterns, different acquisition solutions may be adopted respectively. Further, for different types of portions in the first target etch pattern, corresponding acquisition solutions may be adopted respectively.

For example, for the first target etch pattern including only the curved contour, or a curved contour portion in the first target etch pattern, the first sampling points may be acquired at preset intervals. For a straight-line contour portion in the first target etch pattern, any point may be selected as the first sampling point, and the etching bias correction performed on the first sampling point is equivalent to the correction performed on the entire straight-line edge.

S102: optical proximity effect correction is performed on the first target etch pattern to obtain a first mask pattern.

The etching bias needs to be acquired first to finally obtain the desired target mask pattern. At this time, photolithography simulation and etching simulation need to be performed by virtue of simulation technology, and the premise of simulation is that there is a corresponding mask pattern. Therefore, optical proximity effect correction may be firstly performed on the first target etch pattern to obtain the first mask pattern. There is still a certain difference between the first mask pattern obtained at this time and the final desired target mask pattern, and determining the first mask pattern is only an intermediate step of the design process.

It should be noted that, most of the current optical proximity effect correction techniques are only effective for a Manhattan pattern. The Manhattan pattern refers to a pattern whose shape and edges are mainly composed of lines in horizontal and vertical directions. However, the first target etch pattern in the present application includes a curved contour. Therefore, before performing the optical proximity effect correction, Manhattanization may be firstly performed on the first target etch pattern, and then the optical proximity effect correction may be performed based on the obtained Manhattan pattern to obtain the corresponding first mask pattern.

S103: photolithography simulation is performed on the first mask pattern to obtain a first photolithography pattern, and photolithography etching simulation is performed on the first mask pattern to obtain a first etch pattern.

After obtaining the first mask pattern, photolithography simulation is performed on it to obtain the first photolithography pattern, and photolithography etching simulation is performed on it to obtain the first etch pattern. The photolithography simulation simulates an actual photolithography process, while the photolithography etching simulation simulates an actual photolithography process and etching process. The photolithography simulation and etching simulation may be both implemented by corresponding simulation models.

It should be noted that, during the photolithography etching simulation, the first photolithography pattern can be directly used as the result of the photolithography simulation, i.e., the first etch pattern can be obtained by directly performing etching simulation on the first photolithography pattern.

S104: for each of the first sampling points, a first etching deviating data between a position corresponding to a first sampling point on the first photolithography pattern and a position corresponding to the first sampling point on the first etch pattern is determined individually.

The first photolithography pattern and the first etch pattern are both obtained by simulation based on the first mask pattern, and the first mask pattern is obtained by performing optical proximity effect correction on the first target etch pattern. Therefore, for the plurality of first sampling points acquired on the first target etch pattern, there are corresponding positions on both the first photolithography pattern and the first etch pattern. Thus, for each of the first sampling points, a corresponding position on the first photolithography pattern and a corresponding position on the first etch pattern may be acquired individually, and then based on a bias between the two positions, the first etching deviating data of the first sampling point between the corresponding positions on the first photolithography pattern and the first etch pattern may be determined.

It should be noted that, the embodiments of the present application does not limit the specific contents of the first etching bias data. As an optional embodiment, the first etching bias data may include a deviating distance and a deviating direction of the first sampling point.

S105: for each of the first sampling points, etching bias correction is performed on the first sampling point based on the first etching deviating data to obtain a plurality of second sampling points.

As mentioned above, the first etching deviating data may include the deviating distance and the deviating direction of the first sampling point. Therefore, each of the first sampling points may be moved based on the deviating distance and the deviating direction corresponding to the first sampling point to achieve etching bias correction, thereby obtaining the plurality of second sampling points correspondingly.

Specifically, since the etching bias correction needs to compensate the bias caused by etching, for each of the first sampling points, it may be moved by the corresponding deviating distance in an opposite direction of the corresponding deviating direction, such that the mask pattern obtained based on the second sampling points may eliminate the bias caused by etching.

S106: a target mask pattern is determined based on the plurality of second sampling points.

After obtaining the plurality of second sampling points, the target mask pattern needs to be determined based on these second sampling points. It should be noted that, for the second sampling points, only the etching bias correction is performed, and in actual production, there is also photolithography bias caused by photolithography process. Therefore, it is necessary to perform photolithography bias correction, that is, optical proximity effect correction.

At present, optical proximity effect correction is typically aiming at pattern correction, and only effective for Manhattan pattern. Therefore, it is necessary to generate a corresponding pattern based on the plurality of second sampling points, then Manhattanization is performed on the pattern, and optical proximity effect correction is performed based on the obtained Manhattan pattern to obtain a corresponding mask pattern. At this time, the mask pattern obtained after optical proximity effect correction may be directly used as the target mask pattern. Alternatively, the above process may be repeated based on this mask pattern to continuously update a value of the etching bias to obtain a more accurate etching bias, thereby obtaining a target mask pattern that better meets the requirements.

In addition, it should be noted that, when generating the corresponding pattern based on the plurality of second sampling points, different solutions may be adopted for different types of patterns. For example, for each of the first sampling points on the curved contour, a smooth curve may be used for connecting each of the first sampling points to obtain a corrected curved contour. For a straight-line portion in the first target etch pattern, as mentioned above, any point on the straight-line edge may be selected as the first sampling point corresponding to the straight-line edge. Therefore, a moving distance of the first sampling point is a moving distance of the entire straight-line edge. Typically, a moving direction of the straight-line edge is a direction perpendicular to the straight-line edge.

In the mask pattern determination method provided in the embodiments of the present application, the target mask pattern is determined based on the plurality of second sampling points, and the second sampling points are obtained by performing etching bias correction on the first sampling point based on the first etching deviating data between a position corresponding to a first sampling point on the first photolithography pattern and a position corresponding to the first sampling point on the first etch pattern. The first sampling point may represent the pattern contour of the first target etch pattern. Therefore, in the present application, the etching bias of the curved contour may be corrected relatively accurately by correcting the plurality of sampling points individually. Thus, in the embodiments of the present application, the design of the mask pattern corresponding to the curved pattern may be effectively implemented.

The embodiments of the present application provide a feasible implementation to improve the design efficiency of the target mask pattern. Specifically, when determining the target mask pattern based on the plurality of second sampling points, a target photolithography pattern may be generated based on the plurality of second sampling points, then optical proximity effect correction is performed on the target photolithography pattern, and the obtained mask pattern may be directly determined as the target mask pattern.

In this embodiment, the second sampling points are obtained by performing the etching bias correction on the first sampling points using the first etching bias data, that is, the etching bias correction is completed. Then, the optical proximity effect correction is performed based on the second sampling points, and the desired target mask pattern may be obtained effectively. Thus, the target mask pattern may be obtained quickly. According to the solution provided in the present application, the etching bias correction and optical proximity effect correction are performed on the curved contour, thereby ensuring that the obtained target mask pattern meets the design requirements.

The above embodiments provide a feasible implementation for determining the target mask pattern. The present disclosure further provides another feasible implementation to further improve the accuracy of etching bias correction. Specifically, a target photolithography pattern may be generated based on the second sampling points, and after performing optical proximity effect correction, a mask pattern may be obtained. For this mask pattern, since the etching bias correction and optical proximity effect correction are performed, the mask pattern obtained at this time is more accurate than the first mask pattern obtained for the first time. Therefore, the simulation may be performed based on this mask pattern to further obtain a more accurate etching bias, and steps such as etching bias correction and optical proximity effect correction may be performed again to obtain a mask pattern that better meets actual needs. In practical applications, the above process may be repeated until a sufficiently accurate mask pattern is obtained.

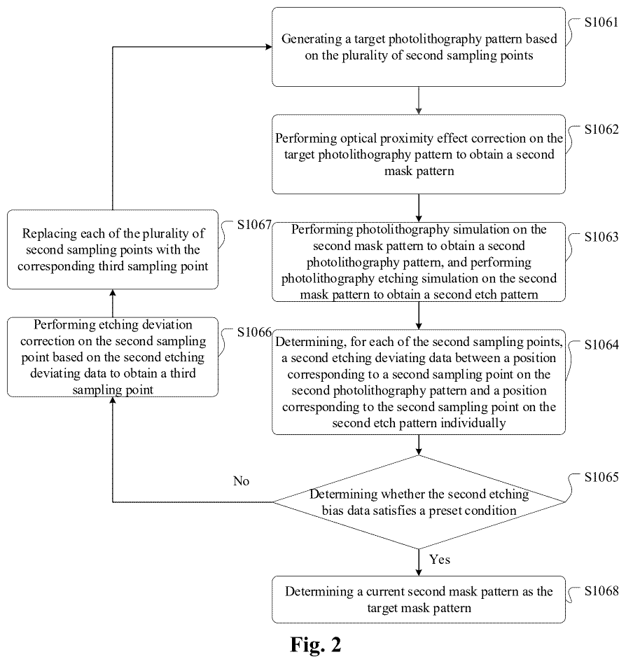

The above process will be described below with reference to the drawings. FIG. 2 shows a flow chart of a second mask pattern determination method according to an embodiment of the present application. As shown in FIG. 2, S106 may include following steps S1061 to S1068.

S1061: a target photolithography pattern is generated based on the plurality of second sampling points.

As mentioned above, when generating the target photolithography pattern based on the plurality of second sampling points, different solutions may be adopted for different types of patterns. For example, for each of the first sampling points on the curved contour, a smooth curve may be used for connecting each of the first sampling points to obtain a corrected curved contour. For a straight-line portion in the first target etch pattern, the straight-line edge may be moved to coincide with a corresponding first sampling point.

S1062: optical proximity effect correction is performed on the target photolithography pattern to obtain a second mask pattern.

Since most of the current optical proximity effect correction techniques are only effective for Manhattan pattern, before performing optical proximity effect correction, Manhattanization may be performed on the first target etch pattern, and then optical proximity effect correction may be performed based on the obtained Manhattan pattern to obtain the corresponding first mask pattern.

S1063: photolithography simulation is performed on the second mask pattern to obtain a second photolithography pattern, and photolithography etching simulation is performed on the second mask pattern to obtain a second etch pattern.

Here, the second etch pattern may be directly obtained by performing etching simulation on the second photolithography pattern. Specifically, a second photolithography pattern may be obtained by performing photolithography simulation on the second mask pattern, and then a second etch pattern may be obtained by performing etching simulation on the second photolithography pattern.

S1064: for each of the second sampling points, a second etching deviating data between a position corresponding to a second sampling point on the second photolithography pattern and a position corresponding to the second sampling point on the second etch pattern are determined individually.

The embodiments of the present application does not limit the specific contents of the second etching bias data. As an optional embodiment, the second etching deviating data may include a deviating distance and a deviating direction of the second sampling point.

S1065: it is determined whether the second etching deviating data satisfies a preset condition; when the second etching deviating data does not satisfy the preset condition, S1066 is executed; and when the second etching deviating data satisfies the preset condition, S1068 is executed.

S1066: etching bias correction is performed on the second sampling point based on the second etching deviating data to obtain a third sampling point.

S1067: each of the plurality of second sampling points is replaced with the corresponding third sampling point.

After obtaining the third sampling point, returning to S1061 until the second etching deviating data satisfies the preset condition.

S1068: a current second mask pattern is determined as the target mask pattern.

The preset condition is not limited here. As an optional embodiment, the preset condition may be that a difference between two second etching biases corresponding to two adjacent iteration processes is less than a threshold. The threshold here may be set according to actual needs. When the difference between the second etching biases corresponding to two adjacent iteration processes is not large, it means that the second etching bias obtained at this time is sufficiently accurate, and thus the iteration may be stopped. Then, the finally obtained second mask pattern is determined as the target mask pattern.

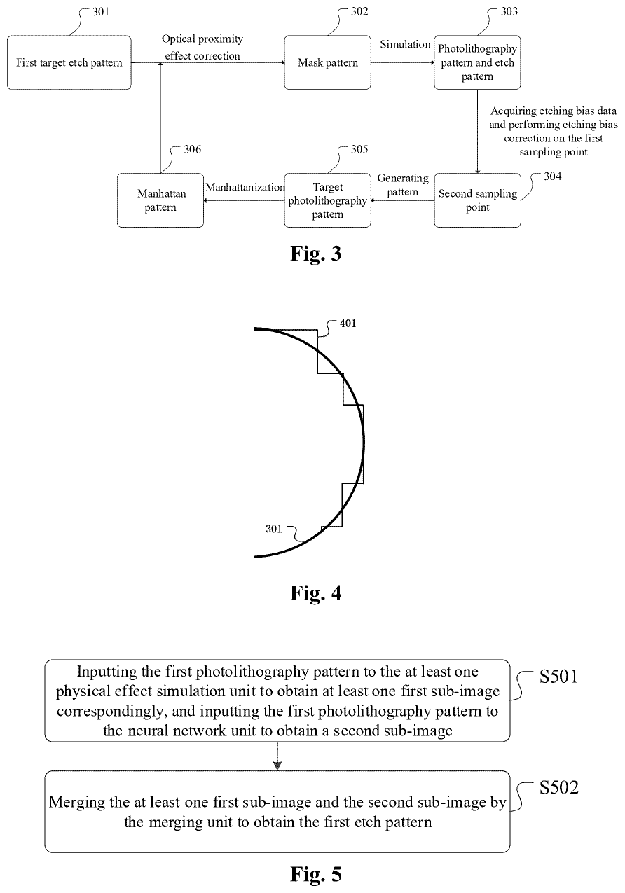

The above solution for determining the target mask pattern will be described below with reference to another drawing. FIG. 3 shows a flow chart of determining a target mask pattern by multiple iterations according to an embodiment of the present application. As shown in FIG. 3, the optical proximity effect correction is performed on a first target etch pattern to obtain a mask pattern 302 (a first mask pattern at this time), and then the simulation is performed to obtain a photolithography pattern and an etch pattern 303 (a first photolithography pattern and a first etch pattern at this time). A first etching bias data is obtained based on these two patterns. After performing etching bias correction on a first sampling point based on the first etching bias data, a second sampling point 304 is obtained. Then, a target photolithography pattern 305 is generated, and Manhattanization is performed on the target photolithography pattern 305 to obtain a Manhattan pattern 306. Optical proximity effect correction is performed on the Manhattan pattern 306 to obtain a mask pattern 302 again (a second mask pattern at this time).

Further, the simulation is performed again based on the mask pattern 302 to obtain a photolithography pattern and an etch pattern 303 (a second photolithography pattern and a second etch pattern at this time). A second etching deviating data is obtained based on these two patterns. After performing etching bias correction on a first sampling point based on the second etching deviating data, a new second sampling point 304 is obtained. Then, a target photolithography pattern 305 and a Manhattan pattern 306 are generated to obtain a new mask pattern 302. The process is repeated until the second etching deviating data satisfies a preset condition. The final mask pattern 302 is determined as a target mask pattern.

In this embodiment, the second etching deviating data is continuously calibrated through multiple iterations to determine an accurate second etching deviating data. Then, etching bias correction may be performed on the first sampling point based on the second etching deviating data to obtain a target mask pattern with a relatively high accuracy.

As mentioned above, most of the current optical proximity effect correction solutions can process only a Manhattan pattern. Therefore, before performing optical proximity effect correction on the first target etch pattern, it is necessary to firstly perform Manhattanization on the first target etch pattern, and then perform the optical proximity effect correction based on the obtained Manhattan pattern to obtain the first mask pattern.

FIG. 4 shows a schematic view of performing Manhattanization on a first target etch pattern according to an embodiment of the present application. As shown in FIG. 4, Manhattanization is performed on a first target etch pattern 301 to obtain a Manhattan pattern 401, and the Manhattan pattern 401 is composed of horizontal and vertical edges.

In this embodiment, by performing Manhattanization on the first target etch pattern, a Manhattan pattern on which the optical proximity effect correction can be performed is obtained. Then, the optical proximity effect correction can be performed based on the obtained Manhattan pattern. In this manner, a corresponding first mask pattern may be obtained quickly.

In practical applications, the first target etch pattern may include a curved contour and a straight-line contour. For the curved contour portion and the straight-line contour portion, different sampling point acquisition methods may be adopted to obtain more suitable first sampling points.

Specifically, as a feasible embodiment, acquiring a plurality of first sampling points for representing a pattern contour of the first target etch pattern includes following steps: acquiring, for a straight-line contour in the first target etch pattern, at least one point on a straight line as a feature point; acquiring, for a curved contour in the first target etch pattern, curved contour points at preset intervals; and at last, determining the feature point and the curved contour points as the first sampling points.

It should be noted that, a specific size of the preset interval is not limited here and may be set according to actual needs. If a higher correction accuracy is required, a relatively small preset interval may be set; and if higher computing efficiency is required, a relatively large preset interval may be set.

In this embodiment, curved contour points are acquired at preset intervals, and at least one point on the straight line is acquired as the feature point, thereby obtaining a plurality of first sampling points on the pattern. In this method, it may be ensured not only that the extracted sampling points may accurately represent the first target etch pattern, but also the acquisition method is simple, and the number of acquired first sampling points is small, thereby reducing the calculation difficulty.

In practical applications, as an optional embodiment, the simulation of the corresponding process may be performed by a photolithography simulation model and an etching simulation model to quickly obtain the required first photolithography pattern and first etch pattern. Specifically, acquiring a first photolithography pattern after photolithography simulation on the first mask pattern, and acquiring a first etch pattern after photolithography simulation and etching simulation on the first mask pattern may include inputting the first mask pattern to a photolithography simulation model to obtain the first photolithography pattern; and inputting the first photolithography pattern to an etching simulation model to obtain the first etch pattern.

The above photolithography simulation model reproduces a photolithography process through a series of calculations and simulations to predict and optimize a photolithography result. The photolithography simulation is mainly based on optical theories, such as wave optics theory, and simulates light emitted from a light source and irradiated onto a mask through optical systems (such as lenses, mirrors, among others).

For the etching simulation model, a feasible embodiment is provided here. The etching simulation model may include a merging unit, a neural network unit, and at least one physical effect simulation unit. FIG. 5 shows a flow chart of a third mask pattern determination method according to an embodiment of the present application. As shown in FIG. 5, a step of inputting the first photolithography pattern to an etching simulation model to obtain the first etch pattern includes S501 and S502.

S501: the first photolithography pattern is input to at least one physical effect simulation unit to obtain at least one first sub-image correspondingly, and the first photolithography pattern is input to the neural network unit to obtain a second sub-image.

The physical effect simulation unit is configured to simulate some physical effects in an actual etching process, such as micro-loading effect and aperture effect. The mask pattern is input to different physical effect simulation units, and the first sub-image after corresponding processing can be obtained. For example, a Gaussian convolution term may be used to simulate a diffusion process.

The neural network unit is trained based on photolithography pattern samples and corresponding etch image labels. Adding the neural network unit to the etching model may greatly improve a data fitting ability of the etching model. In this manner, the problem in the existing modeling method that a desirable model calibration result cannot be quickly obtained according to a measurement result due to the complex etching process is solved. That is, the speed and accuracy of model calibration are improved.

In addition, there may be a problem of over-fitting in the neural network unit. In this embodiment, an actual physical effect is simulated by the physical effect simulation unit, which prevents the model from over-fitting. Moreover, when training the neural network unit, model training may be performed based on a large number of Scanning Electron Microscope (SEM) image data, which may further mitigate the problem of over-fitting of the neural network model.

S502: at least one first sub-image and the second sub-image are merged by the merging unit to obtain the first etch pattern.

FIG. 6 shows a schematic view of a simulation process of an etching simulation model according to an embodiment of the present application. As shown in FIG. 6, a first photolithography pattern 601 is firstly acquired, and then an optical image 602 of the first photolithography pattern 601 is generated. The optical image 602 is input to each physical effect simulation unit to obtain each first sub-image 603 correspondingly, and the optical image 602 is input to the neural network unit to obtain a second sub-image 604. Finally, each first sub-image 603 and the second sub-image 604 are merged by the merging unit of the etching model to obtain a first etch image 605 after the first photolithography pattern being etched.

In this embodiment, images are generated by the physical effect simulation unit and the neural network unit and merged, and the physical effect simulation unit simulates an actual physical effect, which may prevent the etching simulation model from over-fitting. The neural network unit may effectively improve a data fitting ability of the etching simulation model, thereby improving an accuracy of the etching simulation model to obtain an accurate first etching deviating data.

As mentioned above, the first etching bias data may include a deviating distance and a deviating direction. Therefore, for each of the first sampling points, a deviating distance and a deviating direction between a position corresponding to a first sampling point on the first photolithography pattern and a position corresponding to the first sampling point on the first etch pattern may be determined individually. Correspondingly, a step of performing, for each of the first sampling points, etching bias correction on the first sampling point based on the first etching bias data to obtain a plurality of second sampling points may include moving each of the first sampling points by the corresponding deviating distance in an opposite direction of the deviating direction to obtain the plurality of second sampling points.

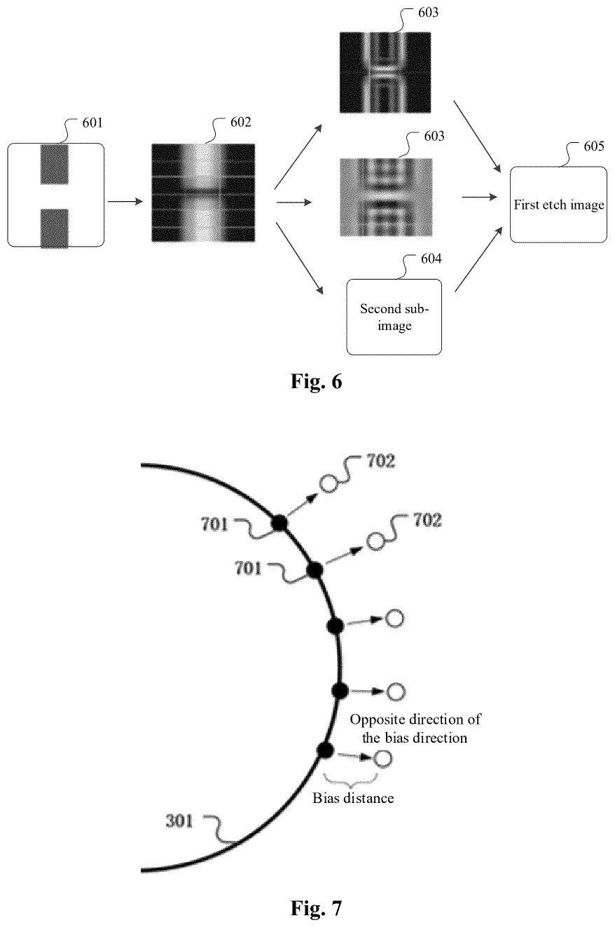

FIG. 7 shows a schematic view of etching bias correction according to an embodiment of the present application. As shown in FIG. 7, first, a plurality of first sampling points 701 of the first target etch pattern 301 are acquired, and then each of the first sampling points 701 is moved by a corresponding deviating distance in an opposite direction of a corresponding bias direction to obtain a plurality of second sampling points 702.

In this embodiment, for each of the first sampling points, the etching bias correction is performed using the corresponding deviating direction and deviating distance, such that the etching bias correction of each of the first sampling points may be performed more accurately, thereby obtaining accurate second sampling points. Thus, the target mask pattern obtained based on the second sampling points may better meet actual requirements.

In the present application, the curved contour is represented by extracting pattern sampling points, and the corresponding etching bias is obtained and corrected for each sampling point, thereby ensuring that each position on the curve may be corrected more accurately. The solution of the present application will be described below in a specific embodiment.

First, a plurality of first sampling points of the first target etch pattern are acquired. For different types of curved contours, different sampling point acquisition methods may be adopted. For example, for a straight-line contour in the first target etch pattern, at least one point on a straight line is acquired as a feature point; for a curved contour in the first target etch pattern, curved contour points at preset intervals are acquired; and the feature point and the curved contour points are determined as the first sampling points.

Then, optical proximity effect correction is performed on the first target etch pattern to obtain a first mask pattern. Specifically, Manhattanization is performed on the first target etch pattern to obtain a corresponding Manhattan pattern; and optical proximity effect correction is performed on the obtained Manhattan pattern to obtain the first mask pattern.

Next, the photolithography simulation is performed on the first mask pattern to obtain a first photolithography pattern, and the photolithography etching simulation is performed on the first mask pattern to obtain a first etch pattern. Specifically, the above process may be performed by a photolithography simulation model and an etching simulation model. The etching simulation model may include a merging unit, a neural network unit, and at least one physical effect simulation unit. The first photolithography pattern may be input to the at least one physical effect simulation unit to obtain at least one first sub-image correspondingly, and the first photolithography pattern may be input to the neural network unit to obtain a second sub-image; the at least one first sub-image and the second sub-image are merged by the merging unit to obtain the first etch pattern.

For each of the first sampling points, a first etching bias data between a position corresponding to a first sampling point on the first photolithography pattern and a position corresponding to the first sampling point on the first etch pattern is determined individually. For example, a deviating distance and a deviating direction of a first sampling point at a corresponding position are determined. Then, each of the first sampling points is moved by the corresponding deviating distance in an opposite direction of the deviating direction to obtain the plurality of second sampling points.

Finally, a target mask pattern is determined based on the plurality of second sampling points. A target photolithography pattern may be generated based on the plurality of second sampling points. Then, optical proximity effect correction is directly performed on the target photolithography pattern to obtain a target mask pattern. Alternatively, multiple iterations may also be used to obtain a more accurate target mask pattern.

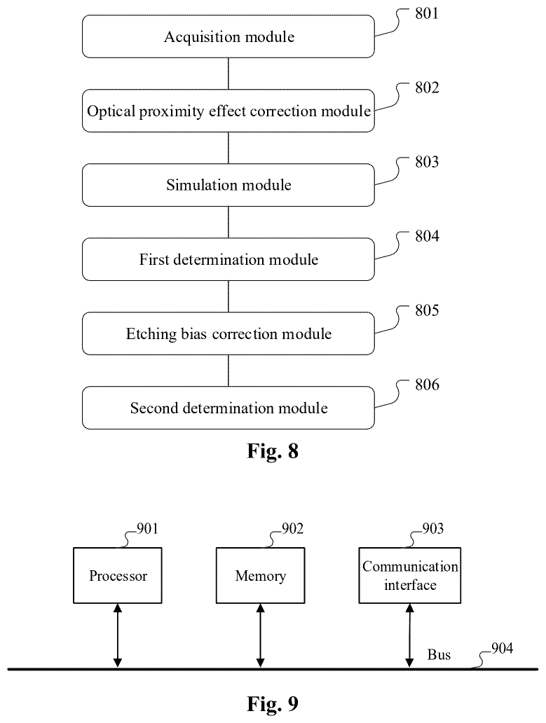

In order to solve the above technical problem, the embodiments of the present application further provide a mask pattern determination apparatus. FIG. 8 shows a schematic structural view of a mask pattern determination apparatus according to an embodiment of the present application. As shown in FIG. 8, the apparatus includes following modules: an acquisition module 801, configured to acquire a first target etch pattern and a plurality of first sampling points for representing a pattern contour of the first target etch pattern, the pattern contour including a curved contour; an optical proximity effect correction module 802, configured to perform optical proximity effect correction on the first target etch pattern to obtain a first mask pattern; a simulation module 803, configured to perform photolithography simulation on the first mask pattern to obtain a first photolithography pattern, and perform photolithography etching simulation on the first mask pattern to obtain a first etch pattern; a first determination module 804, configured to determine, for each of the first sampling points, a first etching deviating data between a position corresponding to a first sampling point on the first photolithography pattern and a position corresponding to the first sampling point on the first etch pattern individually; an etching bias correction module 805, configured to perform, for each of the first sampling points, etching bias correction on the first sampling point based on the first etching deviating data to obtain a plurality of second sampling points; and a second determination module 806, configured to determine a target mask pattern based on the plurality of second sampling points.

In the embodiments of the present application, the target mask pattern is determined based on the plurality of second sampling points, and the second sampling points are obtained by performing the etching bias correction on the first sampling point based on the first etching deviating data between a position corresponding to a first sampling point on the first photolithography pattern and a position corresponding to the first sampling point on the first etch pattern. The first sampling point may characterize the pattern contour of the first target etch pattern. Therefore, in the present application, an etching bias of the curved contour may be corrected relatively accurately by correcting the plurality of sampling points individually. Thus, in the embodiments of the present application, the design of the mask pattern corresponding to the curved pattern may be effectively implemented.

The apparatus provided in the embodiments of the present application corresponds to the method in the aforesaid embodiments. Therefore, the apparatus and the method have the same embodiments and beneficial effects, and details are not repeated here.

In some embodiments, the second determination module 806 is specifically configured to generate a target photolithography pattern based on the plurality of second sampling points; perform the optical proximity effect correction on the target photolithography pattern to obtain a second mask pattern; perform the photolithography simulation on the second mask pattern to obtain a second photolithography pattern, and perform the photolithography etching simulation on the second mask pattern to obtain a second etch pattern; determine, for each of the second sampling points, a second etching bias data between a position corresponding to a second sampling point on the second photolithography pattern and a position corresponding to the second sampling point on the second etch pattern individually; perform, in a case that the second etching deviating data does not satisfy a preset condition, etching bias correction on the second sampling point based on the second etching deviating data to obtain a third sampling point; replace each of the plurality of second sampling points with the corresponding third sampling point, and return to a step of generating a target photolithography pattern based on the plurality of second sampling points until the second etching deviating data satisfies the preset condition; and determine a current second mask pattern as the target mask pattern in a case that the second etching deviating data satisfies the preset condition.

In some embodiments, the second determination module 806 is specifically configured to generate a target photolithography pattern based on the plurality of second sampling points; and perform optical proximity effect correction on the target photolithography pattern to obtain the target mask pattern.

In some embodiments, the optical proximity effect correction module 802 is specifically configured to perform Manhattanization on the first target etch pattern to obtain a corresponding Manhattan pattern; and perform the optical proximity effect correction on the Manhattan pattern to obtain the first mask pattern.

In some embodiments, the first target etch pattern includes a curved contour and a straight-line contour.

The acquisition module 801 is specifically configured to acquire, for a straight-line contour in the first target etch pattern, at least one point on a straight line as a feature point; acquire, for a curved contour in the first target etch pattern, curved contour points at preset intervals; and determine the feature point and the curved contour points as the first sampling points.

In some embodiments, the first determination module 804 is specifically configured to determine, for each of the first sampling points, a deviating distance and a deviating direction between a position corresponding to a first sampling point on the first photolithography pattern and a position corresponding to the first sampling point on the first etch pattern individually.

The etching bias correction module 805 is specifically configured to move each of the first sampling points by the corresponding deviating distance in an opposite direction of the deviating direction to obtain the plurality of second sampling points.

In some embodiments, the simulation module 803 is specifically configured to input the first mask pattern to a photolithography simulation model to obtain the first photolithography pattern; and input the first photolithography pattern to an etching simulation model to obtain the first etch pattern.

In some embodiments, the etching simulation model includes a merging unit, a neural network unit, and at least one physical effect simulation unit. The simulation module 803 is specifically configured to input the first photolithography pattern to the at least one physical effect simulation unit to obtain at least one first sub-image correspondingly, and input the first photolithography pattern to the neural network unit to obtain a second sub-image, the neural network unit being trained based on a photolithography pattern sample and a corresponding etch image label; and merge the at least one first sub-image and the second sub-image by the merging unit to obtain the first etch pattern.

FIG. 9 shows a schematic structural view of a hardware of a mask pattern determination apparatus according to an embodiment of the present application. As shown in FIG. 9, the mask pattern determination apparatus may include a processor 901 and a memory 902 storing computer program instructions.

Specifically, the processor 901 may include a Central Processing Unit (CPU), or an Application Specific Integrated Circuit (ASIC), or may be configured as one or more integrated circuits for implementing the embodiments of the present application.

Memory 902 may include mass memory for data or instructions. By way of example but not limitation, the memory 902 may include the Hard Disk Drive (HDD), the floppy disk drive, the flash memory, the optical disk, the magneto-optical disk, the magnetic tape, or the Universal Serial Bus (USB) drive, or a combination of two or more thereof. Where appropriate, the memory 902 may include the removable or non-removable (or fixed) medium. Where appropriate, the memory 902 may be internal or external to the integrated gateway disaster recovery device. In a particular embodiment, the memory 902 is the non-volatile solid state memory.

The memory 902 may include the Read-Only Memory (ROM), the Random Access Memory (RAM), the magnetic disk storage medium device, the optical storage medium device, the flash memory device, the electrical, optical, or other physical/tangible memory storage device. Accordingly, the memory 902 generally includes one or more tangible (non-transitory) computer-readable storage media (such as, memory device) of software that may be encoded with computer-executable instructions and, the software, when executed (for example by one or more processors), is operable to perform the operations described in the methods according to the above aspects of the present application.

The processor 901 implements any one of the mask pattern determination methods in the above embodiments by reading and executing the computer program instructions stored in the memory 902.

In an example, the mask pattern determination apparatus may further include a communication interface 903 and a bus 904. The processor 901, the memory 902, and the communication interface 903 are connected to each other by the bus 904 and communicate with each other.

The communication interface 903 is mainly configured to implement communication between various modules, apparatus, units and/or devices in the embodiments of the present application.

The bus 904 includes hardware, software or both thereof for coupling the components of the mask pattern determination apparatus to each other. By way of example but not limitation, the bus may include Accelerated Graphical Port (AGP) or other graphical bus, Enhanced Industry Standard Architecture (EISA) bus, Front Side Bus (FSB), Hyper Transport (HT) interconnect, Industry Standard Architecture (ISA) bus, the infinite bandwidth interconnect, Low Pin Count (LPC) bus, memory bus, Micro Channel Architecture (MCA) bus, Peripheral Component Interconnect (PCI) bus, PCI-Express (PCI-X) bus, Serial Advanced Technology Attachment (SATA) bus, Video Electronics Standards Association Local Bus (VLB) bus, or other suitable bus, or a combination of two or more thereof. Where appropriate, the bus 904 may include one or more buses. Although the embodiments of the present application describe and illustrate particular buses, any suitable bus or interconnect is contemplated by the present application.

In addition, the embodiments of the present application may provide a computer storage medium for implementing the mask pattern determination method in the above embodiments. The computer storage medium has stored thereon computer program instructions which, when executed by a processor, implement any one of the mask pattern determination methods in the above embodiments.

The embodiments of the present application further provide a computer program product including a computer program which, when executed by a processor, implements any one of the mask pattern determination methods in the above embodiments.

It should be noted that, this application is not limited to the specific configurations and processes described above and illustrated in the drawings. For the sake of brevity, a detailed description of known methods is omitted here. In the embodiments described above, a number of specific steps have been described and shown as examples. However, the method processes of the present application are not limited to the specific steps described and illustrated herein, and those skilled in the art can make various changes, modifications, and additions, or change the order between steps, after understanding the gist of the present application.

The functional blocks shown in the block diagrams described above may be implemented in hardware, software, firmware, or a combination thereof. When implemented in hardware, it may be, for example, an electronic circuit, an ASIC, appropriate firmware, a plug-in, a function card, and so on. When implemented in software, the elements of the present application are programs or code segments used to perform the required tasks. The programs or code segments may be stored in a machine-readable medium or transmitted over a transmission medium or communication link by a data signal carried in a carrier wave. The “machine-readable medium” may include any medium that can store or transmit information. Examples of the machine-readable medium include an electronic circuit, a semiconductor memory device, an ROM, a flash memory, an Erasable ROM (EROM), a floppy disk, a Compact Disc Read-Only Memory (CD-ROM), an optical disk, a hard disk, an optical fiber medium, a Radio Frequency (RF) link, and so on. The code segments may be downloaded via a computer network, such as the Internet, an intranet, or the like.

It should also be noted that, the exemplary embodiments mentioned in this application describe methods or systems based on a series of steps or apparatus. However, the present application is not limited to the order of the steps described above, that is, the steps may be performed in the order mentioned in the embodiments, or may be performed in an order different from that in the embodiments, or several steps may be performed at the same time.

Aspects of the present application are described above with reference to flow charts and/or block diagrams of the mask pattern determination method, the apparatus, the medium, and the program product according to embodiments of the disclosure. It will be understood that, each block in the flow charts and/or block diagrams, and a combination of any of blocks in the flow charts and/or block diagrams, may be implemented by computer program instructions. These computer program instructions may be provided to a processor of a general purpose computer, a special purpose computer, or other programmable data processing apparatus to produce a machine, such that the instructions, which being executed via the processor of the computer or other programmable data processing apparatus, enable the implementation of the functions/actions specified in one or more blocks in the flow charts and/or block diagrams. Such a processor may be, but is not limited to, a general purpose processor, a special purpose processor, an application specific processor, or field programmable logic circuit. It should also be understood that, each block in the block diagrams and/or flow charts, and a combination of any of blocks in the block diagrams and/or flow charts, may also be implemented by a special purpose hardware that performs the specified functions or actions, or a combination of special purpose hardware and computer instructions.

The above are only specific implementations of the present application. Those skilled in the art can clearly understand that, for the convenience and brevity of the description, the specific working processes of the above-described systems, modules and controllers can be referred to the corresponding processes in the foregoing method embodiments, which is not repeated here. It should be understood that, the protection scope of this application is not limited to this, and any person skilled in the art can easily think of various equivalent modifications or replacements within the technical scope disclosed in this application, and these modifications or replacements should all be covered within the scope of protection of this application.

What is claimed is:

1. A mask pattern determination method, comprising:
acquiring a first target etch pattern and a plurality of first sampling points for charactering a pattern contour of the first target etch pattern, the pattern contour comprising a curved contour;
performing optical proximity effect correction on the first target etch pattern to obtain a first mask pattern;
performing photolithography simulation on the first mask pattern to obtain a first photolithography pattern;
performing photolithography etching simulation on the first mask pattern to obtain a first etch pattern;
determining, for each of the first sampling points, a first etching deviating data between a position corresponding to the first sampling point on the first photolithography pattern and a position corresponding to the first sampling point on the first etch pattern individually;
performing, on each of the first sampling points, etching bias correction based on the first etching deviating data to obtain a plurality of second sampling points; and
determining a target mask pattern based on the plurality of second sampling points.

2. The mask pattern determination method according to claim 1, wherein the determining a target mask pattern based on the plurality of second sampling points comprises:
generating a target photolithography pattern based on the plurality of second sampling points;
performing optical proximity effect correction on the target photolithography pattern to obtain a second mask pattern;
performing photolithography simulation on the second mask pattern to obtain a second photolithography pattern;
performing photolithography etching simulation on the second mask pattern to obtain a second etch pattern;
determining, for each of the second sampling points, a second etching bias data between a position corresponding to the second sampling point on the second photolithography pattern and a position corresponding to the second sampling point on the second etch pattern individually;
performing, under a condition that the second etching bias data does not satisfy a preset condition, etching bias correction on the second sampling point based on the second etching bias data to obtain a third sampling point;
replacing each of the plurality of second sampling points with the corresponding third sampling point, and returning to a step of generating a target photolithography pattern based on the plurality of second sampling points until the second etching bias data satisfies the preset condition; and
determining a current second mask pattern as the target mask pattern under a condition that the second etching deviating data satisfies the preset condition.

3. The mask pattern determination method according to claim 1, wherein the determining a target mask pattern based on the plurality of second sampling points comprises:
generating a target photolithography pattern based on the plurality of second sampling points; and
performing optical proximity effect correction on the target photolithography pattern to obtain the target mask pattern.

4. The mask pattern determination method according to claim 1, wherein the performing optical proximity effect correction on the first target etch pattern to obtain a first mask pattern comprises:
performing Manhattanization on the first target etch pattern to obtain a corresponding Manhattan pattern; and
performing optical proximity effect correction on the Manhattan pattern to obtain the first mask pattern.

5. The mask pattern determination method according to claim 1, wherein the pattern contour further comprises a straight-line contour; and
the acquiring a plurality of first sampling points for characterizing a pattern contour of the first target etch pattern comprises:
acquiring, for the straight-line contour in the first target etch pattern, at least one point on the straight line as a feature point;
acquiring, for the curved contour in the first target etch pattern, curved contour points at preset intervals; and
determining the feature point and the curved contour points as the first sampling points.

6. The mask pattern determination method according to claim 1, wherein the determining, for each of the first sampling points, a first etching deviating data between a position corresponding to the first sampling point on the first photolithography pattern and a position corresponding to the first sampling point on the first etch pattern individually comprises:
determining, for each of the first sampling points, a deviating distance and a deviating direction between a position corresponding to the first sampling point on the first photolithography pattern and a position corresponding to the first sampling point on the first etch pattern individually; and
the performing, for each of the first sampling points, etching bias correction on the first sampling point based on the first etching deviating data to obtain a plurality of second sampling points comprises:
moving each of the first sampling points by the corresponding deviating distance in an opposite direction to the deviating direction to obtain the plurality of second sampling points.

7. The mask pattern determination method according to claim 2, wherein the determining, for each of the first sampling points, a first etching deviating data between a position corresponding to the first sampling point on the first photolithography pattern and a position corresponding to the first sampling point on the first etch pattern individually comprises:
determining, for each of the first sampling points, a deviating distance and a deviating direction between a position corresponding to the first sampling point on the first photolithography pattern and a position corresponding to the first sampling point on the first etch pattern individually; and
the performing, for each of the first sampling points, etching bias correction on the first sampling point based on the first etching deviating data to obtain a plurality of second sampling points comprises:
moving each of the first sampling points by the corresponding deviating distance in an opposite direction to the deviating direction to obtain the plurality of second sampling points.

8. The mask pattern determination method according to claim 3, wherein the determining, for each of the first sampling points, a first etching deviating data between a position corresponding to the first sampling point on the first photolithography pattern and a position corresponding to the first sampling point on the first etch pattern individually comprises:
determining, for each of the first sampling points, a deviating distance and a deviating direction between a position corresponding to the first sampling point on the first photolithography pattern and a position corresponding to the first sampling point on the first etch pattern individually; and
the performing, for each of the first sampling points, etching bias correction on the first sampling point based on the first etching deviating data to obtain a plurality of second sampling points comprises:
moving each of the first sampling points by the corresponding deviating distance in an opposite direction to the deviating direction to obtain the plurality of second sampling points.

9. The mask pattern determination method according to claim 4, wherein the determining, for each of the first sampling points, a first etching deviating data between a position corresponding to the first sampling point on the first photolithography pattern and a position corresponding to the first sampling point on the first etch pattern individually comprises:
determining, for each of the first sampling points, a deviating distance and a deviating direction between a position corresponding to the first sampling point on the first photolithography pattern and a position corresponding to the first sampling point on the first etch pattern individually; and
the performing, for each of the first sampling points, etching bias correction on the first sampling point based on the first etching deviating data to obtain a plurality of second sampling points comprises:
moving each of the first sampling points by the corresponding deviating distance in an opposite direction to the deviating direction to obtain the plurality of second sampling points.

10. The mask pattern determination method according to claim 5, wherein the determining, for each of the first sampling points, a first etching deviating data between a position corresponding to the first sampling point on the first photolithography pattern and a position corresponding to the first sampling point on the first etch pattern individually comprises:
determining, for each of the first sampling points, a deviating distance and a deviating direction between a position corresponding to the first sampling point on the first photolithography pattern and a position corresponding to the first sampling point on the first etch pattern individually; and
the performing, for each of the first sampling points, etching bias correction on the first sampling point based on the first etching deviating data to obtain a plurality of second sampling points comprises:
moving each of the first sampling points by the corresponding deviating distance in an opposite direction to the deviating direction to obtain the plurality of second sampling points.

11. The mask pattern determination method according to claim 1, wherein the performing photolithography simulation on the first mask pattern to obtain a first photolithography pattern comprises:
inputting the first mask pattern to a photolithography simulation model to obtain the first photolithography pattern; and
the performing photolithography etching simulation on the first mask pattern to obtain a first etch pattern comprises:
inputting the first photolithography pattern to an etching simulation model to obtain the first etch pattern.

12. The mask pattern determination method according to claim 11, wherein the etching simulation model comprises a merging unit, a neural network unit, and at least one physical effect simulation unit; and
the inputting the first photolithography pattern to an etching simulation model to obtain the first etch pattern comprises:
inputting the first photolithography pattern to the at least one physical effect simulation unit to obtain at least one first sub-image correspondingly, and inputting the first photolithography pattern to the neural network unit to obtain a second sub-image, the neural network unit being trained based on a photolithography pattern sample and a corresponding etch image label; and
merging the at least one first sub-image and the second sub-image by the merging unit to obtain the first etch pattern.

13. The mask pattern determination method according to claim 1, wherein the first target etch pattern is a pattern of a silicon photonic device.

14. A mask pattern determination apparatus, comprising a processor and a memory storing computer program instructions, wherein the processor, when executes the computer program instructions, carries out the mask pattern determination method comprising:
acquiring a first target etch pattern and a plurality of first sampling points for charactering a pattern contour of the first target etch pattern, the pattern contour comprising a curved contour;
performing optical proximity effect correction on the first target etch pattern to obtain a first mask pattern;
performing photolithography simulation on the first mask pattern to obtain a first photolithography pattern;
performing photolithography etching simulation on the first mask pattern to obtain a first etch pattern;
determining, for each of the first sampling points, a first etching deviating data between a position corresponding to the first sampling point on the first photolithography pattern and a position corresponding to the first sampling point on the first etch pattern individually;
performing, on each of the first sampling points, etching bias correction based on the first etching deviating data to obtain a plurality of second sampling points; and
determining a target mask pattern based on the plurality of second sampling points.

15. A computer readable storage medium, wherein the computer readable storage medium stores computer program instructions which, when being executed by a processor, carry out the mask pattern determination method comprising:
acquiring a first target etch pattern and a plurality of first sampling points for charactering a pattern contour of the first target etch pattern, the pattern contour comprising a curved contour;
performing optical proximity effect correction on the first target etch pattern to obtain a first mask pattern;
performing photolithography simulation on the first mask pattern to obtain a first photolithography pattern;
performing photolithography etching simulation on the first mask pattern to obtain a first etch pattern;
determining, for each of the first sampling points, a first etching deviating data between a position corresponding to the first sampling point on the first photolithography pattern and a position corresponding to the first sampling point on the first etch pattern individually;
performing, on each of the first sampling points, etching bias correction based on the first etching deviating data to obtain a plurality of second sampling points; and
determining a target mask pattern based on the plurality of second sampling points.

16. A computer program product, wherein when instructions in the computer program product are executed by a processor of an electronic device, the electronic device is caused to carry out the mask pattern determination method according to claim 1.
